(19) United States
(12) Patent Application Publication
(10) Pub. No.: US 2015/0015282 A1
(43) Pub. Date: Jan. 15, 2015

(54) TESTING DEVICE FOR RESISTANCE VALUE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: WEN-TING PENG, Wuhan (CN); JIAN LI, Wuhan (CN); SHI-CHAO WANG, Wuhan (CN); YI-HUNG PENG, New Taipei (TW)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 14/327,708

(22) Filed: Jul. 10, 2014

(30) Foreign Application Priority Data
Jul. 10, 2013 (CN) 2013102875959

(51) Int. Cl. G01R 1/067; G01R 27/02

(52) U.S. Cl. CPC G01R 1/06788; G01R 27/02
USPC 324/724

(57) ABSTRACT

A testing device for testing resistance value includes a base, an operation pole, a sliding device, and a housing for enclosing the base. The base defines a hook receiving slot. A plurality of contact tabs is formed inside the hook receiving slot for contacting pins of the expansion card. A plurality of conductive tabs is formed on the base for being electrically coupled to the contact tabs. A ground terminal is electrically coupled to one of the conductive tabs coupling to the ground pins. The sliding device includes a resilient tab. The resilient tab includes a first end contacting one of the conductive tabs and a second end. The housing includes a connection portion for contacting the second end of the resilient tab and a test terminal electrically coupled to the connection portion.

### FIELD

The present disclosure relates to a device for testing resistance value.

### BACKGROUND

An expansion card comprises a plurality of metal pins. A resistance value of the pins of the expansion card needs to be tested.

### BRIEF DESCRIPTION OF THE DRAWINGS

Implementations of the present technology will now be described, by way of example only, with reference to the attached figures.

FIG. 1 is an exploded, isometric view of an exemplary embodiment of a testing device together with an expansion card.

FIG. 2 is an enlarged view of a circled portion II of FIG. 1.

FIG. 3 is an isometric view of a multimeter.

FIG. 4 is a side view of the base of FIG. 1.

FIG. 5 is an enlarged view of the sliding block and the connection blocks of FIG. 1.

FIG. 6 is an assembled, isometric view of FIG. 1.

FIG. 7 is a cross-sectional view taken along the line VII-VII of FIG. 6.

FIG. 8 is a block diagram of an exemplary embodiment of the testing device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

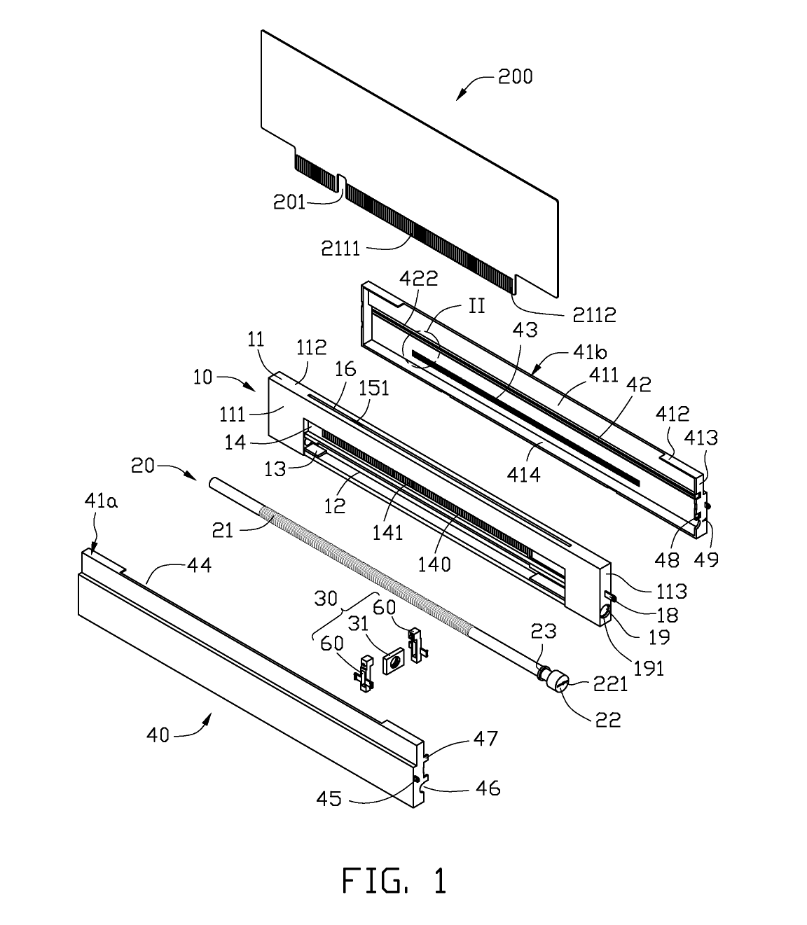

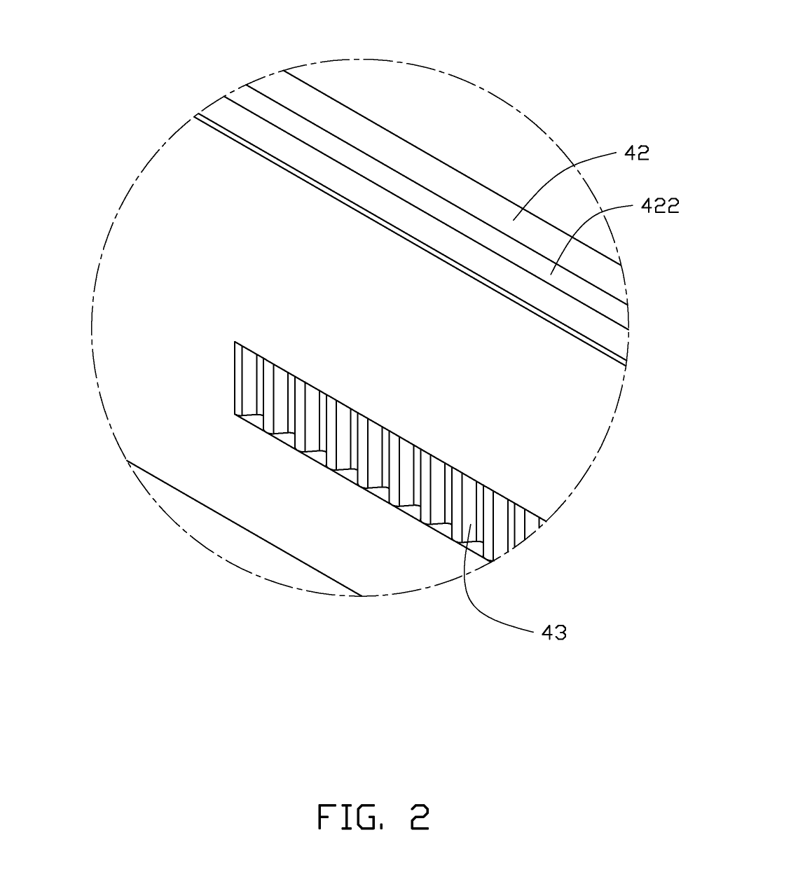

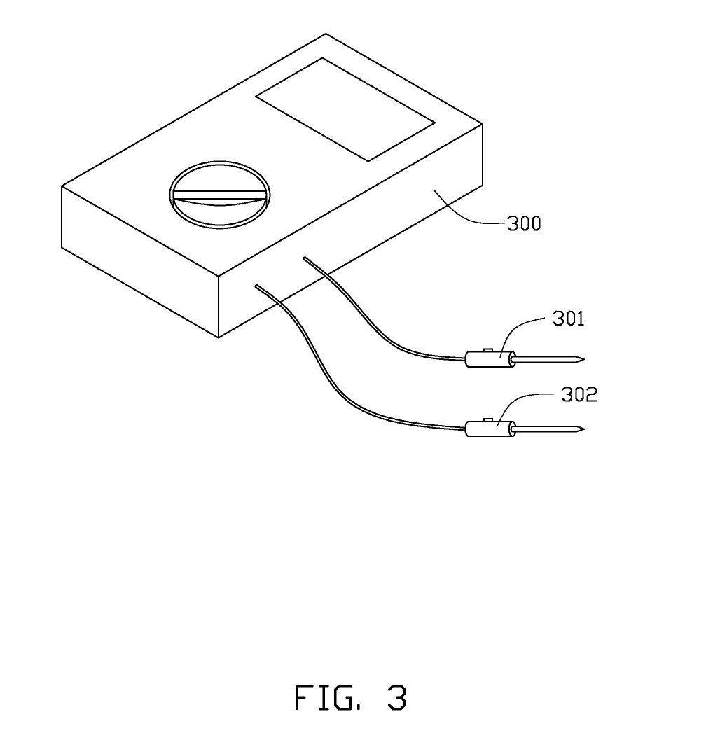

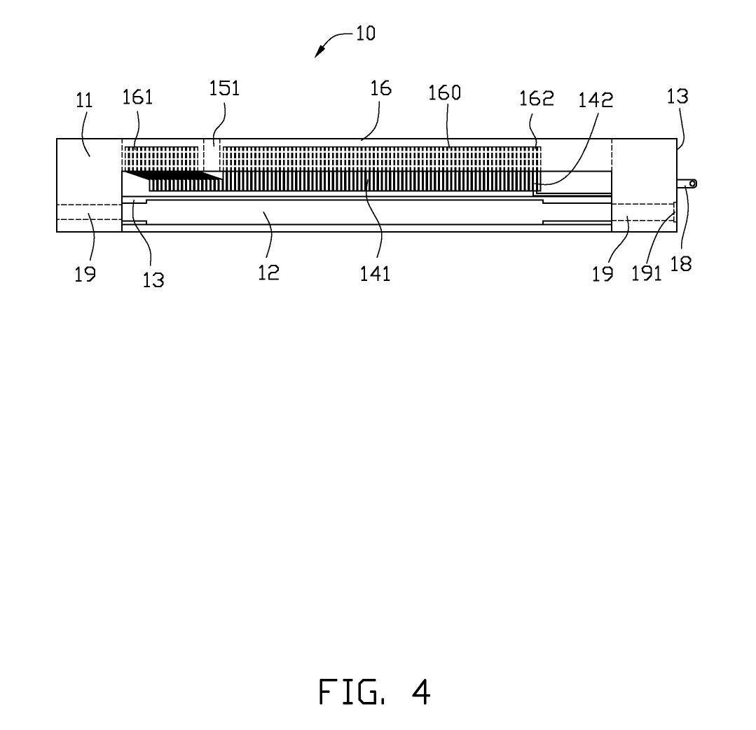

FIGS. 1-4 illustrate an exemplary embodiment of a testing device. The testing device is provided to test resistance value of pins of an expansion card 200 with two multimeters 300. Each multimeter 300 comprises a first probe 301 and a second probe 302.

The pins are located at opposite surfaces of a bottom of the expansion card 200. The pins comprise a plurality of signal pins 2111 and two ground pins 2112. A groove 201 is defined in the bottom of the expansion card 200, and is located between the signal pins 2111.

The testing device comprises a base 10, an operation pole 20 rotatably coupled to the base 10, a sliding device 30 slidably coupled to the operation pole 20, and a housing 40 enclosing the base 10. The sliding device 30 comprises a sliding block 31 and two connection blocks 60.

The base 10 comprises a rectangular main body 11. The main body 11 comprises two opposite side surfaces 111, a top surface 112, and two opposite end surfaces 113. The main body 11 defines a receiving space 12 extending through lower portions of the side surfaces 111. Two blocks 13 are formed inside the receiving space 12, and are located at opposite ends of the receiving space 12. A slide slot 14 is defined in each side surface 111, above the receiving space 12. The top surface 112 defines a hook receiving slot 16. A mounting tab 151 is formed inside the hook receiving slot 16. A plurality of contact tabs 160 is formed inside the hook receiving slot 16. The contact tabs 160 comprise a plurality of positive contact tabs 161 corresponding to the signal pins 2111 and two negative contact tabs 162 corresponding to the ground pins 2112. A plurality of conductive tabs 140 is formed inside the slide slot 14. The conductive tabs 140 comprise a plurality of positive conductive tabs 141 electrically coupled to the positive contact tabs 161 by wires and two negative conductive tabs 142 electrically coupled to the negative contact tabs 162. A ground terminal 18 is attached to one of the end surfaces 113. The ground terminal 18 can be electrically coupled to the negative conductive tabs 142 via wires. Each end surface 113 defines a through hole 19 coupled to the receiving space 12. The one of the end surfaces 113 defines a receiving slot 191 coaxial to the corresponding through hole 19.

A middle of the operation pole 20 forms a thread portion 21. A knob 22 is formed on an end of the operation pole 20. A substantially circular stop tab 23 extends from a circumference of the operation pole 20, near the knob 22. The diameter of the stop tab 23 is smaller than the diameter of the receiving slot 191, and is larger than the diameter of the through holes 19. A pointer 221 is formed on the knob 22.

The housing 40 comprises a first cover 41a and a second cover 41b. Each of the first cover 41a and the second cover 41b comprises a sidewall 411, a top wall 412, an end wall 413, and a bottom wall 414. Each sidewall 411 longitudinally defines a receiving recess 42. A conductive connection portion 422 is formed inside the receiving recess 42. A row of latching slots 43 is defined in the sidewall 411 below the receiving recess 42. The top wall 412 defines a substantially rectangular opening 44. A test terminal 45 extends outward from each end wall 413, and is electrically coupled to the corresponding connection portion 422. A notch 46 is defined in a first edge of each end wall 413 away from the corresponding sidewall 411. Two latches 47 extend from the first edge of the end wall 413 of the first cover 41a. Two latch grooves 48 are defined in the first edge of the end wall 413 of the second cover 41b. A pointer 49 is formed on an outer surface of the end wall 413 of the second cover 41b, near the corresponding notch 46.

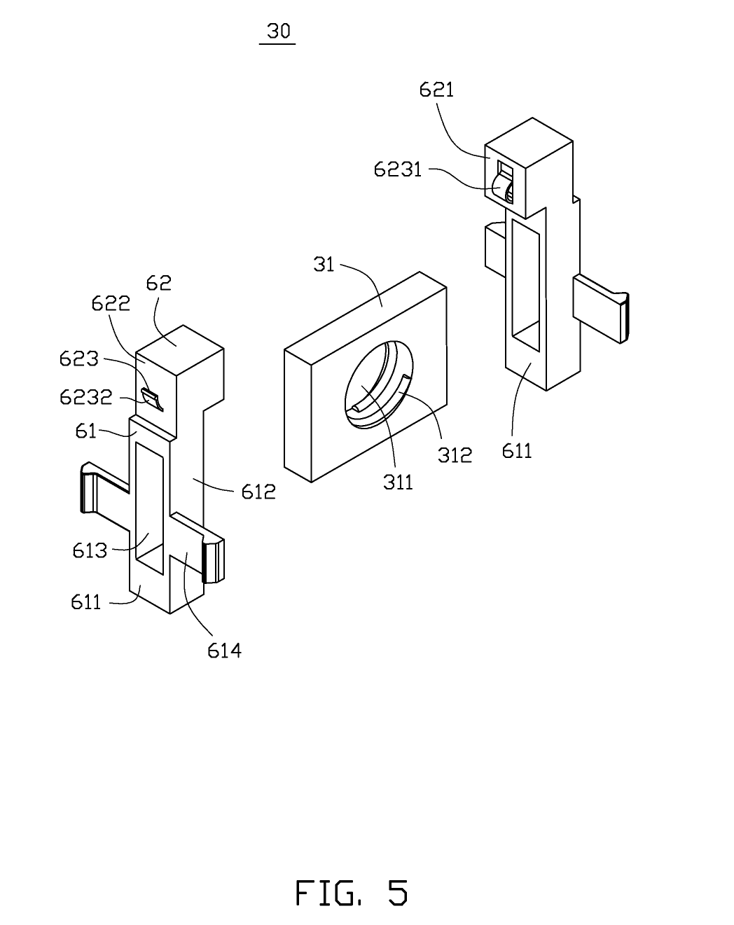

FIG. 5 illustrates that the sliding block 31 can be substantially rectangular. A screw hole 311 is defined in a middle of the sliding block 31. The screw hole 311 comprises a thread portion 312. The pitch of the thread portion 312 is identical to the pitch of the thread portion 21, and is identical to the distance between two neighbor conductive tabs 140.

Each connection block 60 comprises an engaging portion 61 and a sliding portion 62 formed on a top end of the engaging portion 61. The engaging portion 61 is substantially rectangular, comprising two opposite first surfaces 611 and two opposite second surfaces 612. A through slot 613 is defined in the engaging portion 61, extending through the first surfaces 611. Two hooks 614 extend from the second surfaces 612. Each sliding portion 62 comprises a first surface 621 facing the other sliding portion 62, and a second surface 622 opposite to the first surface 621. A conductive resilient tab 623 is attached to each sliding portion 62. The resilient tab 623 comprises a first end 6231 extending outside the sliding portion 62 through the first surface 621, and a second end 6232 extending outside the sliding portion 62 through the second surface 622.

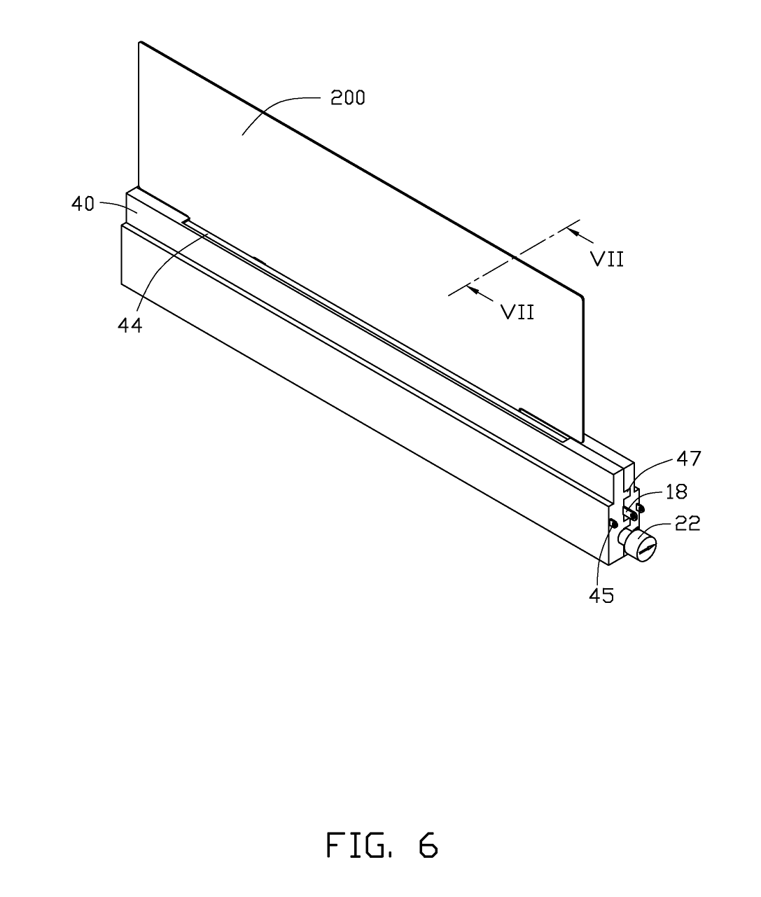

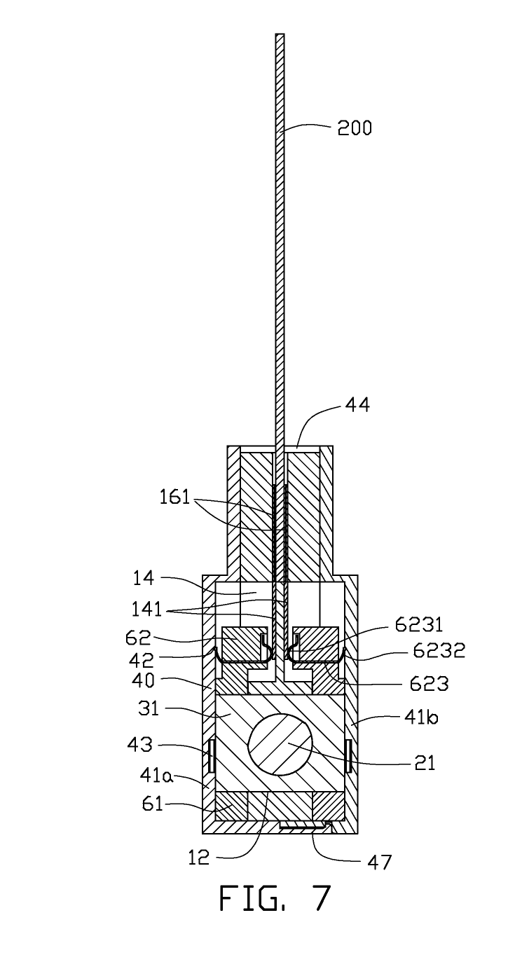

FIGS. 6-7 illustrate the assembly of the testing device. The sliding block 31 is received in the receiving space 12. An end of the operation pole 20 away from the knob 22 extends through the through hole 19 near the receiving slot 191 and the screw hole 311, and extends into the other through hole 19. The stop tab 23 is received in the receiving slot 191. The thread portion 21 of the operation pole 20 engages with the thread portion 312 of the screw hole 311.

Opposite ends of the sliding block 31 are engaged in the through slots 613 of the connection blocks 60. The first ends 6231 contact the positive conductive tabs 141 of the slide slots 14. The base 10 is arranged between the first cover 41a and the second cover 41b. The latches 47 of the first cover 41a engage in the latch grooves 48 of the second cover 41b. The operation pole 20 extends through the notches 46. The second ends 6232 of the connection blocks 60 contact the connection portions 422 of the receiving recesses 42. The hooks 614 of the connection blocks 60 respectively engage in the latching slots 43 of the first cover 41a and the second cover 41b.

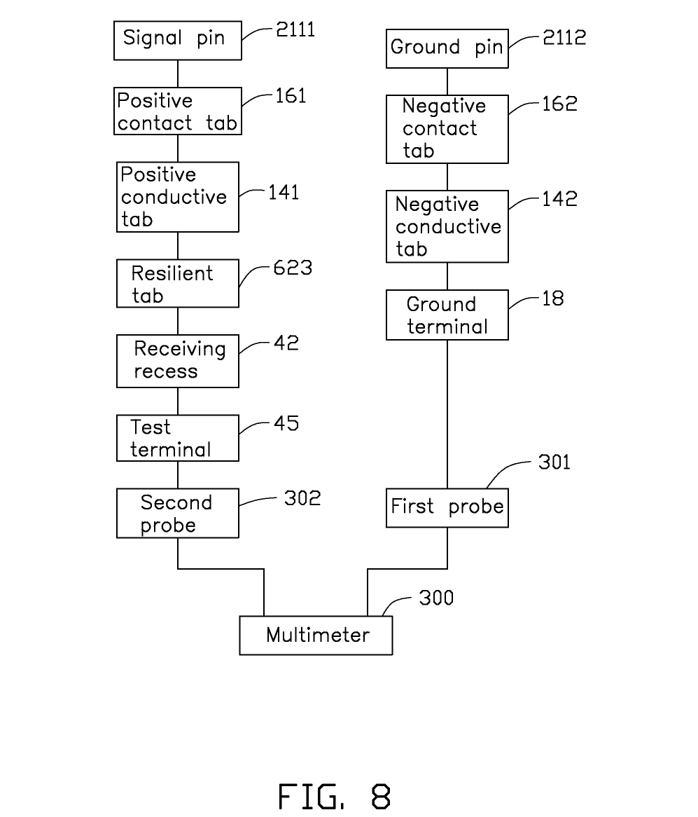

FIG. 8 illustrates the process of testing resistance value of the signal pins 2111 of the expansion card 200. The bottom of the expansion card 200 engages in the openings 44 and the hook receiving slot 16. The mounting tab 151 engages in the groove 201. The first probes 301 of the multimeters 300 are electrically coupled to the ground terminal 18. The second probes 302 are respectively coupled to the test terminals 45. As the knob 22 is rotated, the sliding block 31 abuts against one of the blocks 13 and the pointer 221 and the pointer 49 point the same direction.

The signal pins 2111 contact the positive contact tabs 161. The positive contact tabs 161 are electrically connected to the positive conductive tabs 141. The first end 6231 of each resilient tab 623 contacts one of the positive conductive tabs 141 of the corresponding slide slot 14. The second ends 6232 of the resilient tabs 623 contact the connection portions 422. The connection portions 422 are electrically connected to the test terminals 45. The test terminals 45 are electrically coupled to the second probes 302.

The ground pins 2112 contact the negative contact tabs 162. The negative contact tabs 162 are electrically coupled to the negative conductive tabs 142. The negative conductive tabs 142 are electrically coupled to the ground terminal 18. The ground terminal 18 contacts the first probes 301. Therefore, resistance value of two opposite signal pins 2111 can be obtained with the multimeters 300.

To test other signal pins 2111, the knob 22 is rotated 360 degrees. The connection blocks 60 and the sliding block 31 slide a distance of a pitch of the thread portion 21. The hooks 614 of the connection blocks 60 engage in other latching slots 43. Resistance value of another two opposite signal pins 2111 can be obtained with the multimeters 300.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A testing device for testing a resistance value of signal pins of an expansion card through a multimeter, the testing device comprising:
a base having
a top surface defining a hook receiving slot and a receiving space below the hook receiving slot,
a plurality of contact tabs formed by the base and located within the hook receiving slot, the plurality of contact tabs configured to contact ground pins and the signals of the expansion card;
a plurality of conductive tabs electrically coupled to the contact tabs and being formed on the base,
a ground terminal electrically coupled to one of the conductive tabs and configured to be coupled to the ground pins;
an operation pole configured to received be within the receiving space;
a sliding device slidably coupled to the operation pole and comprising a resilient tab which comprises a first end contacting one of the conductive tabs and a second end; and
a housing for enclosing the base and comprising a connection portion configured to contact the second end of the resilient tab and a test terminal electrically coupled to the connection portion;
wherein, in a first configuration, a first probe of the multimeter is electrically coupled to the ground terminal, and a second probe of the multimeter is electrically coupled to the test terminal.

2. The testing device of claim 1, wherein the sliding device comprises a sliding block for encircling the operation pole and a connection block coupled to the sliding block, the connection block comprises two opposite hooks, the housing defines a row of latching slots, and the hooks engage in two of the latching slots.

3. The testing device of claim 2, wherein the connection block comprises an engaging portion coupled to the sliding block and a sliding portion formed on a top end of the engaging portion, and the resilient tab is attached to the sliding portion.

4. The testing device of claim 1, wherein the housing defines a receiving recess along a direction that the sliding device slides, and the connection portion is formed inside the receiving recess.

5. The testing device of claim 1, wherein the operation pole comprises a knob, a first pointer is formed on the knob, and a second pointer is formed on the housing to point the first pointer.

6. The testing device of claim 5, wherein two through holes are defined in opposite ends of the base and coupled to the receiving space, opposite ends of the operation pole are received in the through holes.

7. The testing device of claim 6, wherein an end of the base defines a receiving slot coaxial to one of the through holes, and the knob is received in the receiving slot.

8. The testing device of claim 1, wherein two slide slots are defined in opposite surfaces of the base, the conductive tabs are formed inside the slide slots, the sliding device comprises a sliding block encircling the operation pole and two connection blocks coupled to opposite ends of the sliding block, each connection block comprises two hooks, the housing comprises a first cover and a second cover, a row of latching slots is defined in each of the first cover and the second cover, the hooks of one of the connection blocks engage in the latching slots of the first cover, and the hooks of the other connection block engage in the latching slots of the second cover.
